(19) United States
(12) Patent Application Publication
(10) Pub. No.: US 2024/0284748 A1
(43) Pub. Date: Aug. 22, 2024

(54) DISPLAY PANEL, DISPLAY APPARATUS AND METHOD FOR MANUFACTURING DISPLAY PANEL

(71) Applicants: Chengdu BOE Optoelectronics Technology Co., Ltd., Chengdu, Sichuan (CN); BOE Technology Group Co., Ltd., Beijing (CN)

(72) Inventors: Cheng ZENG, Beijing (CN); Jaeho LEE, Beijing (CN); Zhen SUN, Beijing (CN); Lulin MA, Beijing (CN); Fei CHEN, Beijing (CN)

(21) Appl. No.: 18/569,266

(22) PCT Filed: Jun. 18, 2021
(86) PCT No.: PCT/CN2021/100929

§ 371 Date: Dec. 12, 2023

(51) Int. Cl. H10K 59/38; H10K 59/122; H10K 59/80

(52) U.S. Cl. CPC H10K 59/38; H10K 59/122; H10K 59/873; H10K 59/877; H10K 59/879; H10K 59/8792

(57) ABSTRACT

The present disclosure provides a display panel, a display apparatus and a method for manufacturing a display panel. The display panel includes: a base substrate; light-emitting elements located on a side of the base substrate; a color conversion film layer located on a side, away from the base substrate, of the light-emitting elements and including a plurality of color conversion patterns in one-to-one correspondence with the light-emitting elements, each color conversion pattern includes a matrix and color conversion particles distributed in the matrix, and the color conversion particles convert light emitted by the light-emitting elements; and a first film layer located between the light-emitting elements and the color conversion film layer and adjacent to the color conversion film layer, a refractive index n1 of the first film layer and a refractive index n2 of the matrix satisfying: n2/n1>0.82.

### TECHNICAL FIELD

The present disclosure relates to the field of semiconductor technologies, and in particular, to a display panel, a display apparatus, and a method for manufacturing the display panel.

### BACKGROUND

The Organic Light Emitting Diode (OLED) display technology has the characteristics of self-luminescence, wide viewing angle, wide color gamut, high contrast, lightness and thinness, foldability, flexibility, portability, and the like, and becomes a main direction for research and development in the display field.

The QD (Quantum-dot) color conversion particle technology is a technology that uses nano-scale semiconductor particles to emit light with a specific frequency by applying a certain electric field or light pressure thereto, and the frequency of the emitted light is related to a diameter of the particle, so that the frequency of the emitted light, that is, color of the emitted light, can be adjusted by adjusting the diameter of the particle.

### SUMMARY

The present disclosure provides a display panel, a display apparatus and a method for manufacturing a display panel. The display panel includes:

a base substrate;

light-emitting elements located on a side of the base substrate;

a color conversion film layer located on a side, away from the base substrate, of the light-emitting elements and including a plurality of color conversion patterns in one-to-one correspondence with the light-emitting elements, each color conversion pattern includes a matrix and color conversion particles distributed in the matrix, and the color conversion particles are configured to convert light emitted by the light-emitting elements; and

a first film layer located between the light-emitting elements and the color conversion film layer and adjacent to the color conversion film layer, a refractive index n1 of the first film layer and a refractive index n2 of the matrix satisfying: n2/n1>0.82.

In some implementations, a critical angle of total reflection at an interface between the first film layer and the matrix is greater than 55°.

In some implementations, the refractive index n1 of the first film layer and the refractive index n2 of the matrix satisfy: n2/n1≥0.91.

In some implementations, the refractive index n1 of the first film layer satisfies: 1.76≤n1≤1.80.

In some implementations, the refractive index n2 of the matrix satisfies: 1.58≤n2≤1.65.

In some implementations, a material of the first film layer includes silicon nitride and silicon oxynitride, where a mass of silicon nitride is m1 and a sum of masses of silicon nitride and silicon oxynitride is m2, and m1 and m2 satisfy: 40%≤m1/m2≤45%.

In some implementations, the display panel further includes an encapsulation layer for light-emitting element between the light-emitting elements and a quantum dot film layer, the encapsulation layer for light-emitting element including a first inorganic encapsulation layer, an organic encapsulation layer located on a side of the first inorganic encapsulation layer away from the light-emitting elements, and a second inorganic encapsulation layer located on a side of the organic encapsulation layer away from the first inorganic encapsulation layer; where the first film layer is the second inorganic encapsulation layer.

In some implementations, the display panel further includes a filling layer between the light-emitting elements and the color conversion film layer, the first film layer being the filling layer.

in some implementation, the display panel further includes an encapsulation layer for quantum dot located between the filling layer and the color conversion film layer, the first film layer being the encapsulation layer for quantum dot.

In some implementations, a material of the matrix includes at least one of a phenolic resin, a polyamide resin, a polyimide, a polyester resin, a polyphenylene resin.

In some implementations, the display panel further includes:

a first pixel defining layer located between the base substrate and the first film layer, the first pixel defining layer having a plurality of first openings; and

a second pixel defining layer located on a side of the first film layer away from the first pixel defining layer, the second pixel defining layer having a plurality of second openings, the color conversion patterns being located in the second openings, and at least part of the second openings being in one-to-one correspondence with the first openings, where

an orthographic projection of each of the at least part of the second openings on the base substrate covers an orthographic projection of the first opening corresponding to the second opening on the base substrate, and a minimum cross-sectional area of each of the at least part of the second openings is larger than a minimum cross-sectional area of the first opening corresponding thereto.

In some implementations, the minimum cross-sectional area S1 of each of the at least part of the second openings and the minimum cross-sectional area S2 of the first opening corresponding thereto satisfy: 1.08≤S2/S1≤1.22.

In some implementations, each color conversion pattern further includes scattering particles distributed in the matrix, at least 80% of the scattering particles having a particle size larger than or equal to 20 nm and less than or equal to 50 nm.

in some implementation, the display panel further includes a low refractive index layer located on a side of the color conversion film layer away from the first film layer, the low refractive index layer having a refractive index larger than or equal to 1.3 and less than or equal to 1.4.

In some implementations, the light-emitting elements emit blue light;

the plurality of color conversion patterns include a red conversion pattern, a green conversion pattern, and a blue conversion pattern, the red conversion pattern including red conversion particles, the green conversion pattern including green conversion particles, and the blue conversion pattern including blue conversion particles or a transparent color filter;

the display panel further includes a black matrix and a plurality of color filters located on a side, away from the color conversion film layer, of the low refractive index layer; the black matrix being provided with a plurality of third openings, and the color filters being located in the third openings; the plurality of color filters including a red color filter corresponding to the red conversion pattern, a green color filter corresponding to the green conversion pattern, and a blue color filter corresponding to the blue conversion pattern.

In some implementations, the color convertion particles include quantum dots.

In some implementations, the light-emitting elements are OLED light-emitting elements.

An embodiment of the present disclosure further provides a display apparatus, which includes the display panel provided in the embodiments of the present disclosure.

An embodiment of the present disclosure further provides a method for manufacturing a display panel, including:

providing a base substrate;

forming a plurality of light-emitting elements on a side of the base substrate;

forming a first film layer on a side of the light-emitting elements away from the base substrate;

forming a color conversion film layer having a plurality of color conversion patterns on a side of the first film layer away from the light-emitting elements, where the color conversion film layer is adjacent to the first film layer, the color conversion patterns each include a matrix and color conversion particles distributed in the matrix, and a refractive index n1 of the first film layer and a refractive index n2 of the matrix satisfy: n2/n1>0.82.

### BRIEF DESCRIPTION OF DRAWINGS

FIG. 1 is a schematic diagram illustrating a principle of a Fabry-Perot interferometer;

FIG. 2A is a curve of an attenuation in brightness of an OLED device with viewing angles;

FIG. 2B is a curve of an attenuation in color cast of an OLED device with viewing angles;

FIG. 3A is curve of an attenuation in brightness of a QD with viewing angles;

FIG. 3B is a curve of an attenuation in color cast of a QD with viewing angles;

FIG. 4A is a curve of an attenuation in brightness of a QD in combination with an OLED with viewing angles;

FIG. 4B is a curve of an attenuation in color cast of a QD in combination with an OLED with viewing angles;

FIG. 5 is a schematic diagram of a display panel according to an embodiment of the present disclosure;

FIG. 6 is a schematic structural diagram of a color conversion pattern according to an embodiment of the present disclosure;

FIG. 7 is a schematic structural diagram of a light-emitting device 2 according to an embodiment of the present disclosure;

FIG. 8 is another schematic structural diagram of a light-emitting device 2 according to an embodiment of the present disclosure;

FIG. 9A is a schematic diagram of a total reflection of an optical path;

FIG. 9B shows a curve of an attenuation in brightness of a R-QD in combination with an OLED with viewing angles;

FIG. 9C is a curve of an attenuation in color cast of a R-QD in combination with an OLED with viewing angles;

FIG. 9D shows a curve of an attenuation in brightness of a G-QD in combination with an OLED with viewing angles;

FIG. 9E shows a curve of an attenuation in color cast of a G-QD in combination with an OLED with viewing angles;

FIG. 10A is another schematic diagram of a display panel according to an embodiment of the present disclosure;

FIG. 10B is another schematic diagram of a display panel according to an embodiment of the present disclosure;

FIG. 10C is another schematic diagram of a display panel according to an embodiment of the present disclosure;

FIG. 11A is another schematic diagram of a display panel according to an embodiment of the present disclosure;

FIG. 11B is a schematic diagram illustrating a relationship between ratios of a first opening to a second opening and brightness according to an embodiment of the present disclosure;

FIG. 12A is a schematic diagram illustrating a relationship between a first opening and a second opening according to an embodiment of the present disclosure;

FIG. 12B is another schematic diagram illustrating a relationship between a first opening and a second opening according to an embodiment of the present disclosure;

FIG. 12C is another schematic diagram illustrating a relationship between a first opening and a second opening according to an embodiment of the present disclosure;

FIG. 13A is another schematic structural diagram of a color conversion pattern according to an embodiment of the present disclosure;

FIG. 13B is another curve of an attenuation in brightness of a R-QD in combination with an OLED with viewing angles;

FIG. 13C is another curve of an attenuation in color cast of a R-QD in combination with an OLED with viewing angles;

FIG. 13D is another curve of an attenuation in brightness of a G-QD in combination with an OLED with viewing angles;

FIG. 13E shows a curve of an attenuation in color cast of a G-QD in combination with an OLED with viewing angles;

FIG. 14 is another schematic diagram of a display panel according to an embodiment of the present disclosure;

FIG. 15 is a schematic diagram of a thin film transistor according to an embodiment of the present disclosure; and

FIG. 16 is a schematic flowchart illustrating a method for manufacturing a display panel according to an embodiment of the present disclosure.

### DETAIL DESCRIPTION OF EMBODIMENTS

In order to make the objects, technical solutions and advantages of the embodiments of the present disclosure more apparent, the technical solutions of the embodiments of the present disclosure will be described clearly and completely below with reference to the drawings of the embodiments of the present disclosure. It is to be understood that the described embodiments are only a few embodiments of the present disclosure, and not all embodiments. All other embodiments, which can be derived by a person skilled in the art from the described embodiments of the disclosure without creative effort, are within the protection scope of the present disclosure.

Unless defined otherwise, technical or scientific terms used herein shall have the ordinary meaning as understood by one of ordinary skill in the art to which the present disclosure belongs. The words “first”, “second”, and the like in the present disclosure are not intended to indicate any order, quantity, or importance, but rather is used to distinguish one element from another. The word “comprising/including”, “comprises/includes”, or the like, means that the element or item preceding the word includes the element or item listed after the word and its equivalent, but does not exclude other elements or items. The word “connected/coupled”, “connecting/coupling” or the like is not restricted to physical or mechanical connections, but may include electrical connections, whether direct or indirect. The word “upper/on/above”, “lower/under/below”, “left”, “right”, or the like is used only to indicate relative positional relationships, and when the absolute position of the object being described is changed, the relative positional relationships may also be changed accordingly.

In order to make the following description of the embodiments of the present disclosure clear and concise, a detailed description of known functions and known components is omitted from the present disclosure.

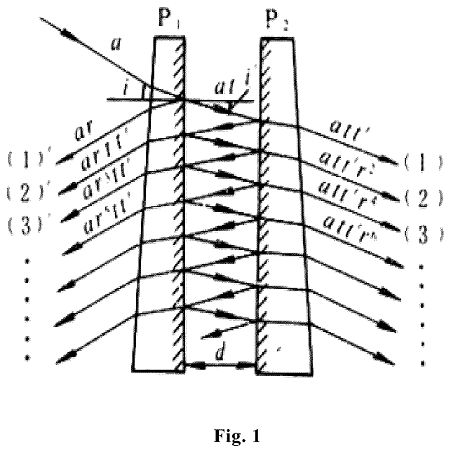

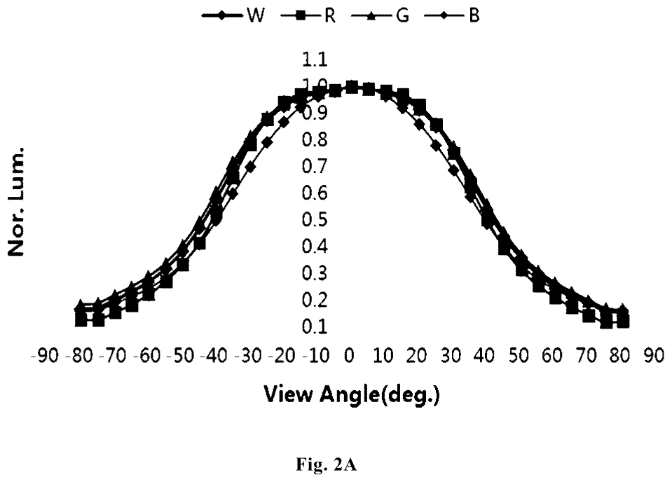

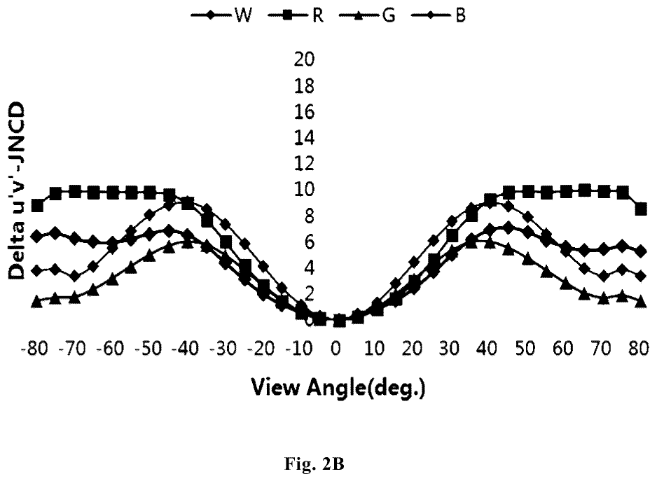

Due to the microcavity structure (the microcavity effect, that is, light at a specific angle may be reflected multiple times between two metal layers to generate a strong interference effect) in the OLED device, as shown in FIG. 1, brightness of a product is attenuated too fast with a change of a viewing angle, which affects the visual effect of the product at a large viewing angle. Meanwhile, due to the inconsistent attenuation speeds of the microcavity effect for R/G/B in the OLED device with the change of the viewing angle, the color cast of the OLED device is caused to change greatly with the change of the viewing angle, that is, the color of the product is not consistent when the product is observed at different viewing angles by naked eyes, which further affects the visual effect of the product at a large viewing angle, as shown in FIG. 2A and FIG. 2B.

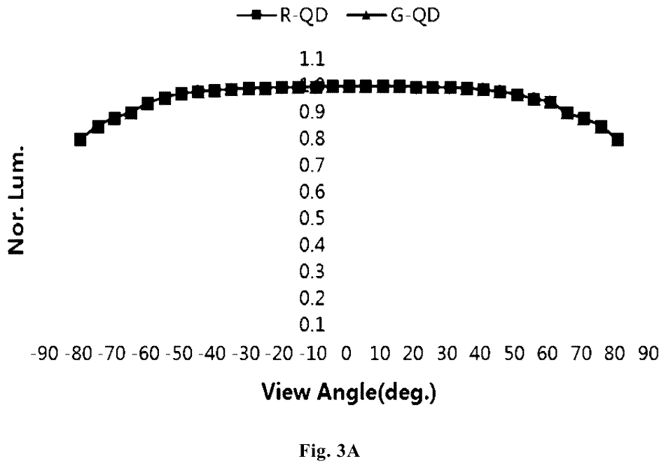

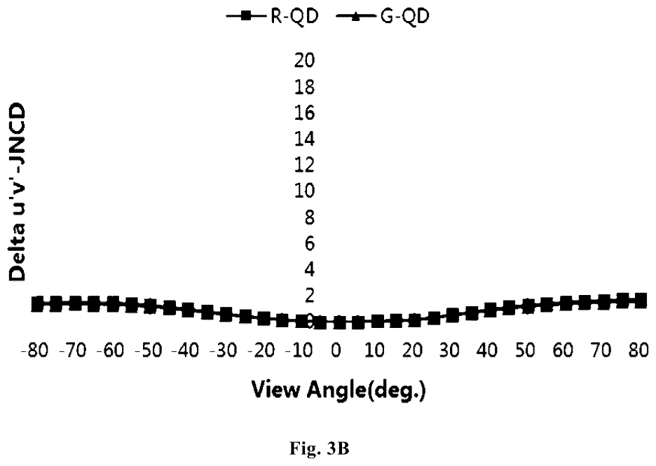

Compared with a self-luminous spectrum of the OLED, a spectrum emitted by the quantum dot has a narrower peak width at half height for R/G/B, is purer and has higher color saturation. Meanwhile, since the light emitted from the quantum dot being excited is isotropic, the problem of fast attenuation in brightness and large change in color cast, caused by the microcavity structure of the OLED device, simulation results of which are shown in FIGS. 3A and 3B, in the visual effect of the product at large viewing angles can be theoretically solved, and it is known from FIGS. 3A and 3B that if the QD technology is used, compared with the OLED device, the attenuation in brightness and the change in the color cast of the product at large viewing angles can be obviously eliminated.

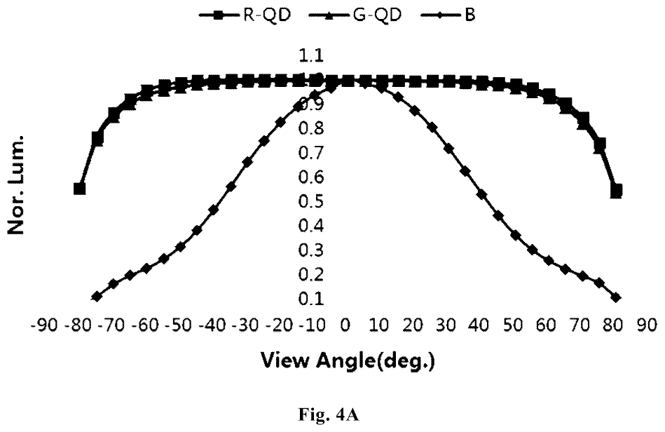

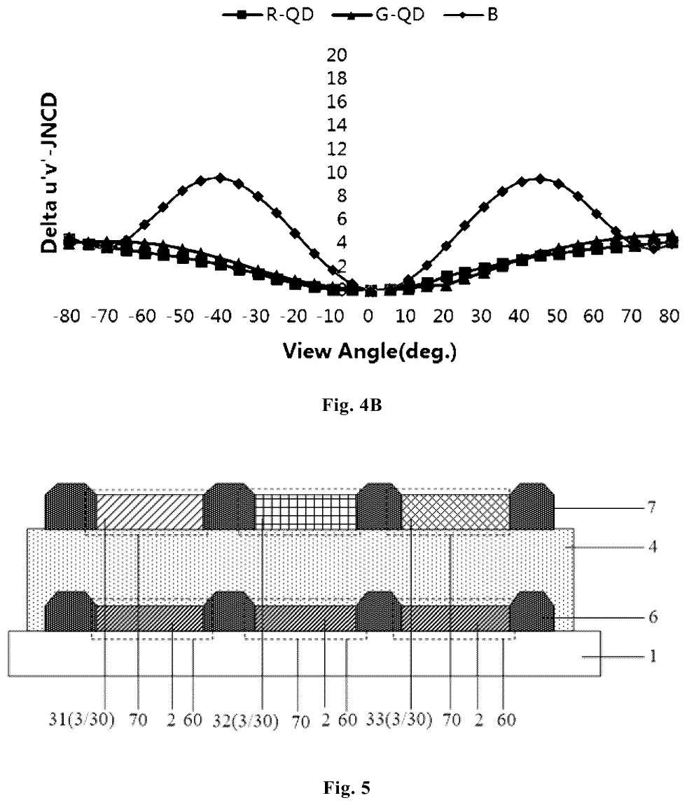

At present, for a display device including QD and OLED, a trend that the changes in brightness and color cast with the viewing angles are shown in FIGS. 4A and 4B, and the brightness of a R-QD display device and a G-QD display device is obviously attenuated after the viewing angle changes by 60 degrees, and the brightness and the chromaticity of the R-QD device and the G-QD display device are obviously changed, and the visual effect of the product is influenced.

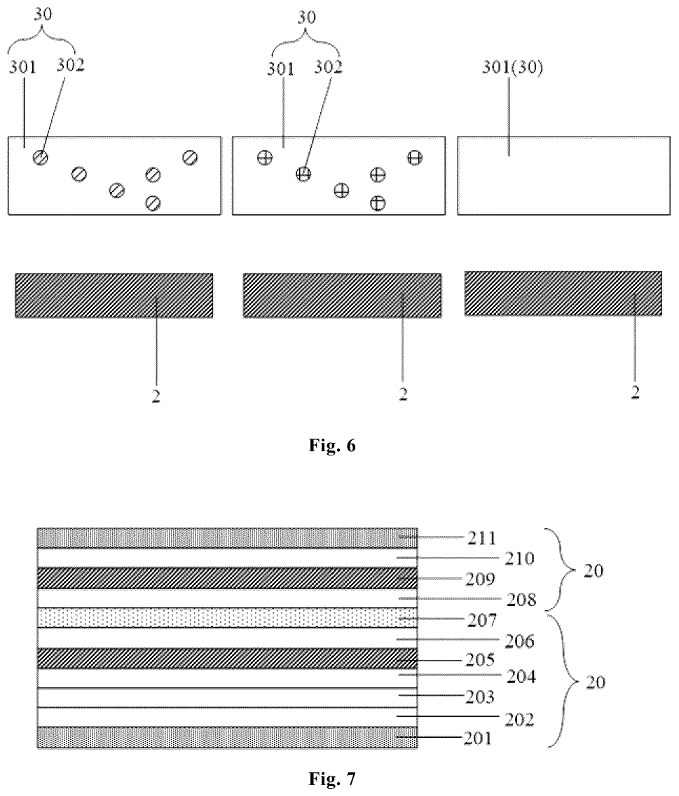

In view of above, referring to FIGS. 5, 6, 7, and 8, an embodiment of the present disclosure provides a display panel, including: a base substrate 1, a light-emitting element 2, a color conversion film layer 3 and a first film layer 4.

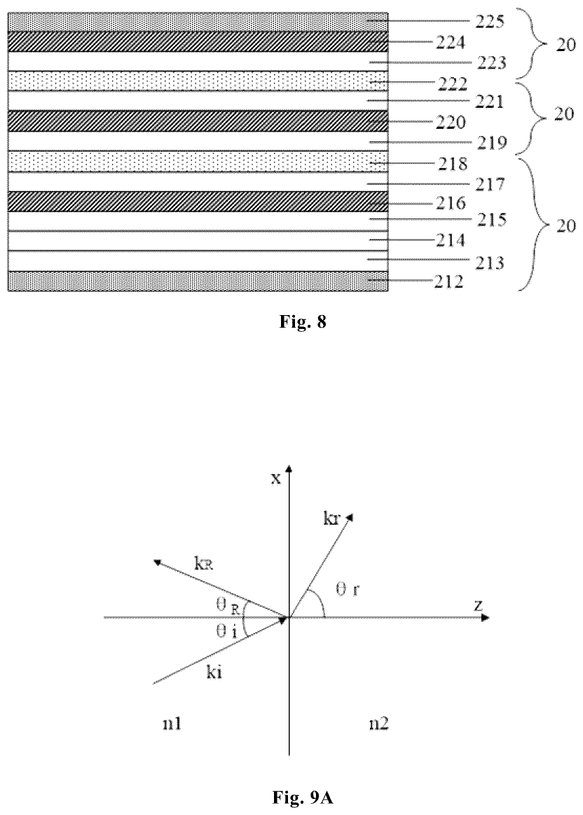

The light-emitting element 2 located on a side of the base substrate 1; specifically, the light-emitting element 2 may be an organic light-emitting device that emits blue light; the light-emitting element 2 may include a plurality of light-emitting sub-elements which are stacked on a side of the substrate base 1 in sequence, for example, as shown in FIG. 7, the light-emitting element 2 includes two light-emitting sub-elements 20 which are stacked. The light-emitting element 2 may specifically include: a first anode 201, a first hole injection layer 202, a first hole transport layer 203, a second hole transport layer 204, a first organic light-emitting layer 205, a first electron transport layer 206, a first charge generation layer 207, a third hole transport layer 208, a second organic light-emitting layer 209, a second electron transport layer 210, and a first cathode 211, which are arranged on a side of the substrate base 1 in sequence; alternatively, for example, as shown in FIG. 8, the light-emitting element 2 includes three light-emitting sub-elements 20 which are stacked, specifically, the light-emitting element 2 may include: a second anode 212, a second hole injection layer 213, a fourth hole transport layer 214, a fifth hole transport layer 215, a third organic light-emitting layer 216, a third electron transport layer 217, a second charge generation layer 218, a sixth hole transport layer 219, a fourth organic light-emitting layer 220, a fourth electron transport layer 221, a third charge generation layer 222, a seventh hole transport layer 223, a fifth organic light-emitting layer 224, and a second cathode 225, which are arranged on a side of the base substrate 1 in sequence.

The color conversion film layer 3 is located on a side of the light-emitting element 2 away from the base substrate 1, and is provided with a plurality of color conversion patterns 30 which are in one-to-one correspondence with light-emitting elements 2, each color conversion pattern 30 includes a matrix 301 and color conversion particles 302 distributed in the matrix 301, and the color conversion particles 302 convert light emitted by the light-emitting element 2; specifically, the plurality of color conversion patterns 30 may include a red conversion pattern 31, a green conversion pattern 32, and a blue conversion pattern 33, the red conversion pattern 31 may absorb light emitted from the light-emitting element 2 and convert it into red light; the green conversion pattern 32 may absorb the light emitted from the light-emitting element 2 and convert it into red light; the blue conversion pattern 33 may be a film layer through which light emitted from the light-emitting element 2 passes; specifically, the color conversion particles 302 may include quantum dots.

The first film layer 4 is located between the light-emitting element 2 and the color conversion film layer 3 and is adjacent to the color conversion film layer 3; a refractive index n1 of the first film layer 4 and a refractive index n2 of the matrix 301 satisfy the following relation: n2/n1>0.82. Specifically, n2/n1 is less than 1. In particular, “one being adjacent to another” may be understood to mean that they are in direct contact with each other.

In the embodiment of the present disclosure, the first film layer 4 adjacent to the color conversion film layer 3 is disposed between the light-emitting element 2 and the color conversion film layer 3, and the refractive index n1 of the first film layer 4 and the refractive index n2 of the matrix 301 satisfy the relation of n2/n1>0.82, which can increase an critical angle of total reflection at an interface between the first film layer 4 and the color conversion film layer 3, increase the amount of light emitted at a large viewing angle, and further eliminate the problem of severe attenuation in brightness and color cast at large viewing angles in the device including QD and OLED in the related art.

In some implementations, the critical angle of total reflection at the interface between the first film layer 4 and the matrix 301 is greater than 55°.

In some implementations, the refractive index n1 of the first film layer 4 and the refractive index n2 of the matrix 301 satisfy the relation: n2/n1>0.91. When n2/n1>0.91, the critical angle of total reflection can be made greater than or equal to 66°, and the amount of light emitted at a large viewing angle can be further increased.

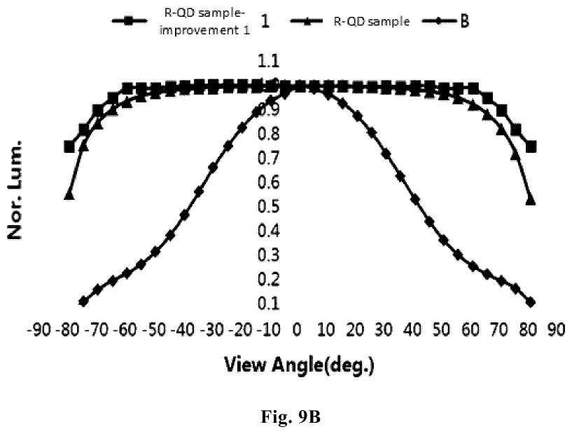

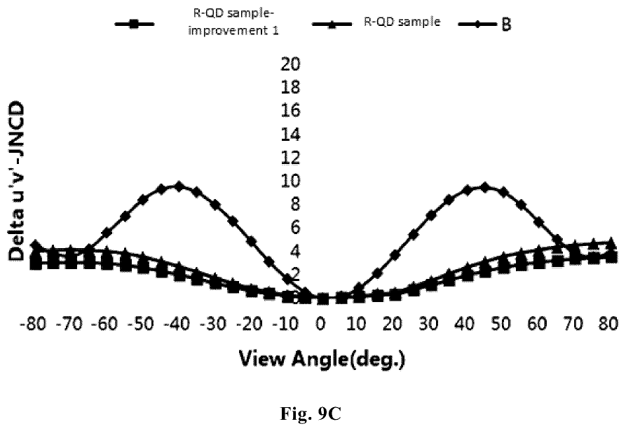

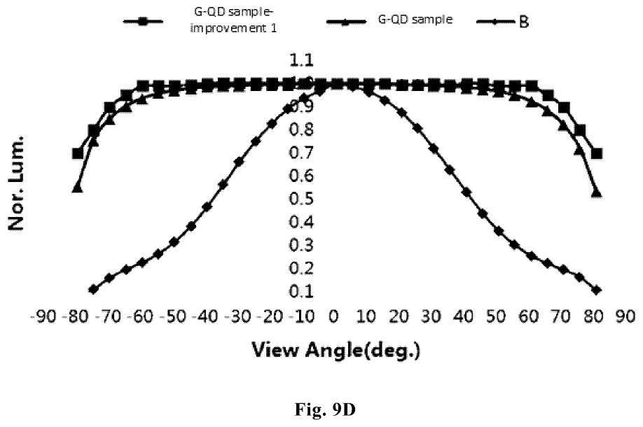

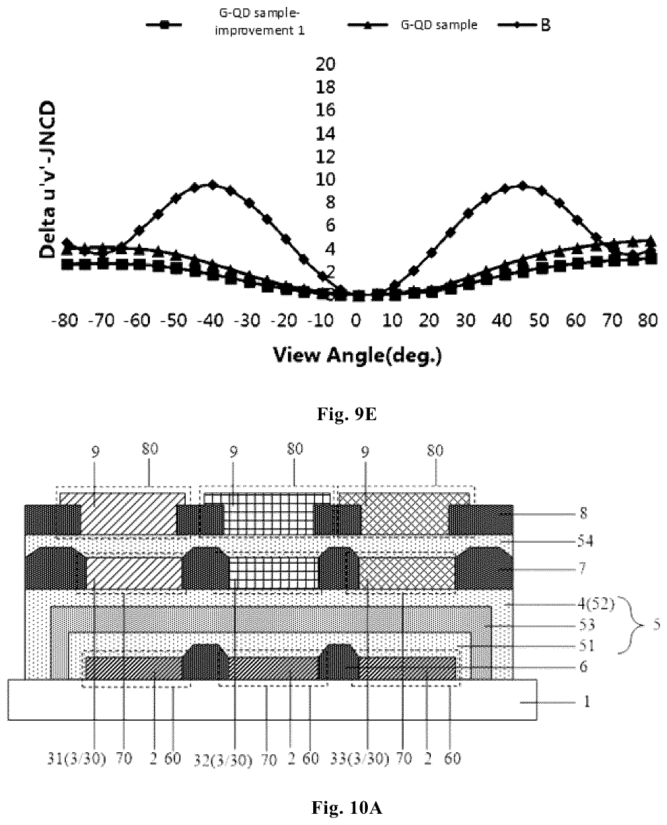

A schematic diagram of the total reflection of the light path is shown in FIG. 9A.

The critical angle θ_{c} at which the total reflection occurs is calculated from the following formula:

$$θ c = θ i = arcsin ( n 2 / n 1 ) .$$

In the embodiment of the present disclosure, the critical angle of total reflection at the interface between the first film layer 4 and the matrix 301 is adjusted by adjusting the refractive indexes of n1 and n2, for example, assuming that n1=1.82 and n2-1.5, the critical angle θ2 of total reflection at the interface between the first film layer 4 and the matrix 301 can be calculated to be 55° from the above formula, that is, θ2=55°. In a case where n2/n1 is greater than 0.82, the critical angle of total reflection can be greater than 55°; for another example, assuming that n1=1.8 and n2=1.65, the critical angle θ2 of total reflection at the interface between the first film layer 4 and the matrix 301 can be calculated to be 66° from the above formula, that is, θ2=66°; in a case where n2/n1 is greater than or equal to 0.91, the critical angle of total reflection can be greater than or equal to 66°.

In some implementations, the refractive index n1 of the first film layer 4 satisfies a relation of 1.76≤n1≤1.80. In the embodiment of the present disclosure, the refractive index n1 of the first film layer 4 and the refractive index n2 of the matrix may satisfy a relation of 0.91≤n2/n1<1 by adjusting the refractive index n1 of the first film layer 4. Specifically, the refractive index n1 of the first film layer 4 may be reduced to be less than or equal to 1.80.

In some implementations, the refractive index n2 of the matrix 301 satisfies a relation of 1.58≤n2≤1.65. In the embodiment of the present disclosure, the refractive index n1 of the first film layer 4 and the refractive index n2 of the matrix 301 may satisfies a relation of 0.91≤n2/n1<1 by adjusting the refractive index n2 of the matrix 301 of the color conversion film layer 3.

In some implementations, a material of the first film layer 4 includes silicon nitride and silicon oxynitride, where a mass of silicon nitride is m1, and a sum of masses of silicon nitride and silicon oxynitride is m2; m1 and m2 satisfy a relation of m1/m2≤45%. In the embodiment of the present disclosure, the material of the first film layer 4 includes silicon nitride and silicon oxynitride, a main function of silicon nitride is blocking moisture and oxygen, the higher the content of silicon nitride is, the stronger the ability of blocking moisture and oxygen is, and meanwhile, the higher the refractive index of the first film layer 4 is, by controlling the mass content of silicon nitride to be less than or equal to 45%, the refractive index n1 of the first film layer 4 can satisfy a relation of n1≤1.80.

In some implementations, m1 and m2 satisfies: m1/m2≥40%. In the embodiment of the present disclosure, the first film layer 4 is generally desired to have other functions, such as a moisture and oxygen blocking performance, and in order to satisfy the moisture and oxygen blocking performance (WVTR<5E-03 g/cm³×day) of the light-emitting element 2, the content of silicon nitride in the first film layer 4 is desired to be greater than or equal to 40%, and accordingly, the refractive index n1 of the first film layer 4 can satisfy a relation of n1≥1.76, so as to avoid the first film layer 4 losing the moisture and oxygen blocking performance when the content of silicon nitride is too low, that is, the first film layer 4 is desired to have a low refractive index and simultaneously is desired to meet a certain encapsulation requirement, the refractive index of the first film layer 4 is positively correlated with a proportion of silicon nitride, and the moisture and oxygen blocking performance is also positively correlated with the proportion of silicon nitride, when the refractive index of the first film layer 4 is desired to be controlled to be less than or equal to 1.8, the proportion of silicon nitride is desired to be less than or equal to 45%, but in order to meet the encapsulation requirement, the proportion of silicon nitride cannot be too low, that is, the proportion of silicon nitride is desired to be greater than or equal to 40%.

Silicon nitride may be represented by SiNx, for example, and silicon oxynitride may be represented by SiNOx, for example. In some embodiments, “x” in “SiNx” may be different from that in “SiNOx”.

In some implementations, silicon nitride may be Si₃N₄ and silicon oxynitride may be SiON, i.e., the material of the first film layer 4 may include Si₃N₄ and SiON, where the mass of Si₃N₄ is m1, and the sum of the masses of Si₃N₄ and SiON is m2; m1 and m2 satisfy: 40%≤m1/m2≤45%. Thus, the first film layer 4 can have a desired refractive index, and at the same time, has a better encapsulation effect.

In a specific implementation, the refractive index n2 of the matrix 301 satisfies: 1.58≤n2≤1.65, the critical angle of total reflection at the interface between the first film layer 4 and the color conversion film layer 3 can be increased, and the amount of light emitted at a large viewing angle can be increased without affecting the performance of the matrix 301.

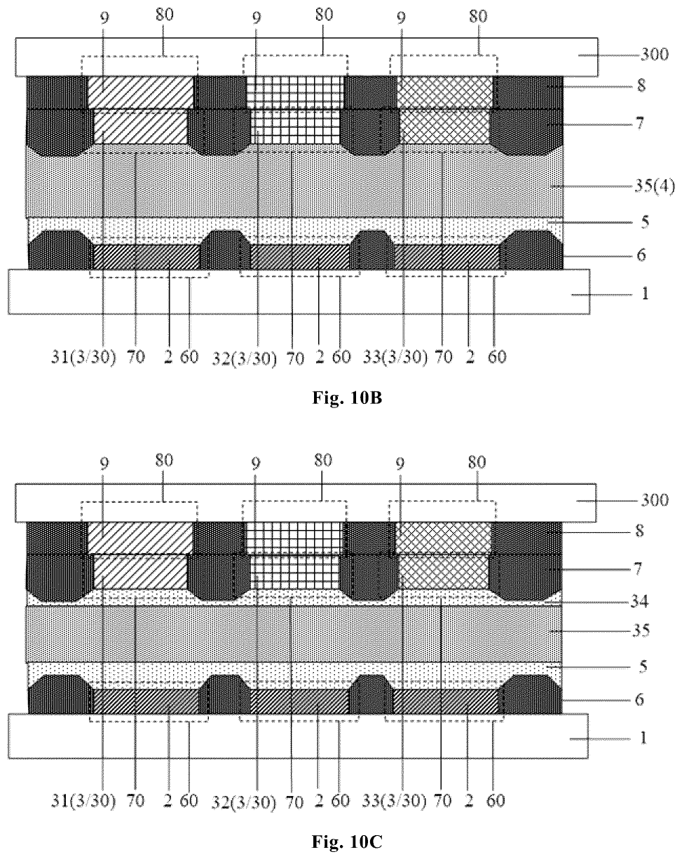

In some implementations, referring to FIG. 10A, the display panel further includes an encapsulation layer 5 for light-emitting element, which is located between the light-emitting element 2 and the color conversion film layer 3 and includes a first inorganic encapsulation layer 51, an organic encapsulation layer 53 located on a side of the first inorganic encapsulation layer 51 away from the light-emitting element 2, and a second inorganic encapsulation layer 52 located on a side of the organic encapsulation layer 53 away from the first inorganic encapsulation layer 51, the first film layer 4 being the second inorganic encapsulation layer 52. In the embodiment of the present disclosure, in a case where the first film layer 4 is the second inorganic encapsulation layer 52, the problem that the critical angle of total reflection at the interface between the first film layer 4 and the color conversion film layer 3 is relatively small and attenuation in brightness and color cast are serious at a large viewing angle occurs, and the attenuation in brightness and color cast at a large viewing angle can be largely eliminated by controlling the refractive index n1 of the first film layer 4 and the refractive index n2 of the matrix 301 to satisfy a relation of 0.91≤n2/n1<1.

It can be understood that, when proper materials of the first film layer 4 and the color conversion film layer 3 are selected to satisfy that n2/n1 is larger than or equal to 1, the total reflection does not occur at the interface between the first film layer 4 and the color conversion film layer 3, and the attenuation in brightness and color cast at a large viewing angle can be largely eliminated.

Specifically, a main material of the first inorganic encapsulation layer 51 may be silicon oxynitride, and has a film thickness ranging from 0.8 μm to 1.0 μm, and a refractive index ranging from 1.70 to 1.75; a main material of the organic encapsulation layer 53 may be methyl methacrylate, and has a film thickness ranging from 8 μm to 12 μm, and a refractive index ranging from 1.50 to 1.60; the second inorganic encapsulation layer 52 may has a thickness ranging from 0.5 μm to 0.8 μm, and a refractive index ranging from 1.76 to 1.80. The first inorganic encapsulation layer 51 and the second inorganic encapsulation layer 52 may be prepared by a chemical vapor deposition, the organic encapsulation layer 53 may be specifically prepared by inkjet printing.

In some implementations, referring to FIG. 10B, a filling layer 35 is arranged between the light-emitting element 2 and the color conversion film layer 3, the first film layer 4 being the filling layer 35. The display panel provided in the embodiment of the present disclosure may be formed by aligning and assembling two substrates to form a cell, that is, a first substrate having the light-emitting element 2 and a second substrate having the color conversion pattern 30 are formed, respectively, and the first substrate and the second substrate are aligned and assembled to form a cell so as to form the display panel; specifically, after the cell is formed, a gap between the first substrate and the second substrate is filled to form the filling layer 35, and in this case, the first film layer 4 may be the filling layer 35. Specifically, a material of the filling layer 35 may be resin, and a refractive index n1 of the resin and the refractive index n2 of the matrix satisfy that n2/n1>0.82.

In some implementations, referring to FIG. 10C, an encapsulation layer 34 for quantum dot is further provided between the filling layer 35 and the color conversion film layer 3, and the encapsulation layer 34 for quantum dot includes the first film layer 4. In the embodiment of the present disclosure, when the display panel is formed by aligning and assembling two substrates to form a cell, before aligning and assembling two substrates to form a cell, a surface of the second substrate formed with the color conversion pattern 30 may be encapsulated to form the encapsulation layer 34 for quantum dot. In some implementations, the first film layer 4 may be the encapsulation layer 34 for quantum dot. In particular, a material of the encapsulation layer 34 for quantum dot may include silicon nitride and silicon oxynitride.

In some implementations, a material of the matrix 301 includes at least one of phenolic resin, polyamide resin, polyimide, polyester resin, and polyphenylene resin. In a specific implementation, by controlling conditions and/or raw materials used in the production of the phenolic resin, the polyamide resin, the polyimide, the polyester resin, and the polyphenylene resin, a refractive index of the resin formed can be made to be larger than or equal to 1.58 and less than or equal to 1.65.

In some implementations, referring to FIG. 11A, the display panel further includes a first pixel defining layer 6 between the base substrate 1 and the first film layer 4, the first pixel defining layer 6 having a plurality of first openings 60; specifically, the organic light-emitting layer of the light-emitting element 2 may be located within the first opening 60.

The display surface further includes a second pixel defining layer 7 located on a side of the first film layer 4 away from the first pixel defining layer 6, the second pixel defining layer 7 having a plurality of second openings 70, at least part of the second openings 70 being in one-to-one correspondence with the first openings 60. For example, the number of the second openings 70 in the second pixel defining layer 7 may be larger than the number of the first openings 6 in the first pixel defining layer 6, so that each first opening 60 corresponds one of the second openings 70. Specifically, the color conversion pattern 30 is located within the second opening 70.

An orthographic projection of each of at least part of the second openings 70 on the base substrate 1 covers an orthographic projection of the first opening 60 corresponding to the second opening 70 on the base substrate 1, and a minimum cross-sectional area of each of the at least part of the second openings 70 is larger than a minimum cross-sectional area of the first opening 60 corresponding thereto. It is understood that, in a practical implementation, a shape of a cross-section of the second opening 70 in a direction perpendicular to the base substrate 1 may be an inverted trapezoid, that is, a dimension of the second opening 70 gradually increases in a direction away from the base substrate 1, in this case, the minimum cross-sectional area of the second opening 70 may be understood as a cross-sectional area of the second opening 70 at a position closest to the base substrate 1; similarly, a shape of a cross-section of the first opening 60 in a direction perpendicular to the base substrate 1 may be an inverted trapezoid, that is, a dimension of the first opening 60 gradually increases in a direction away from the base substrate 1, in this case, the minimum cross-sectional area of the first opening 60 may be understood as a cross-sectional area of the first opening 60 at a position closest to the base substrate 1. It should be noted that the cross-section refers to a cross-section of a structure in a direction perpendicular to a thickness direction of the display panel.

In the embodiment of the present disclosure, the minimum cross-sectional area of each of at least part of the second openings 70 is larger than the minimum cross-sectional area of the first opening 60 corresponding thereto, and by increasing the minimum cross-sectional area of the second opening 70, more backlight at a large viewing angle can enter the color conversion pattern 30, and is not absorbed by the second pixel defining layer 7 (a material of which is the same as that of a black matrix) around the color conversion pattern 30, thereby further eliminating the problem of severe attenuation in brightness and color cast at a large viewing angle.

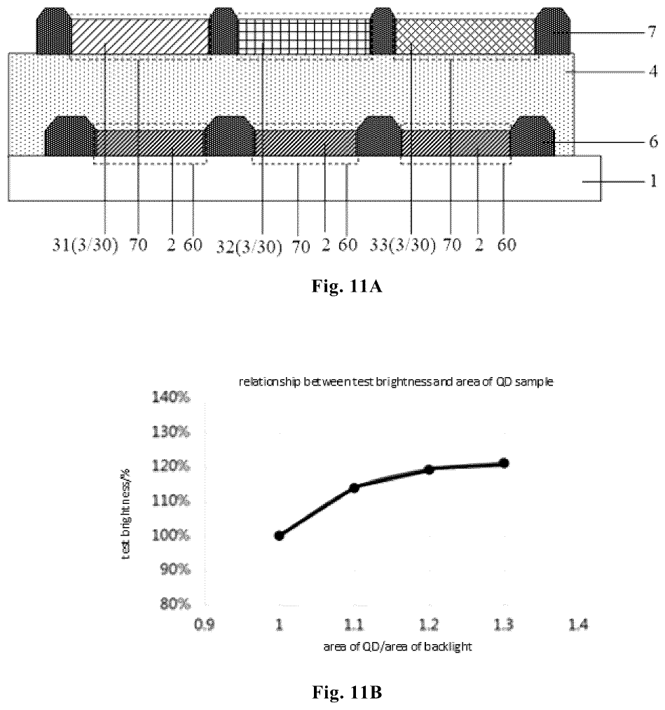

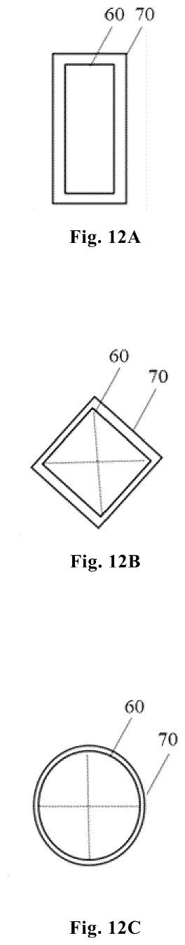

In particular, shapes of the second opening 70 and the first opening 60 corresponding to the second opening 70 may be similar, with centers thereof being coincided. Specifically, the shape of the second opening 70 (i.e., the shape of the color conversion pattern 30) may be rectangular, diamond, circular, or the like. In a case where the shape of the second opening 70 is rectangular, as shown in FIG. 12A, the center of the second opening 70 is at the same position as the center of the first opening 60 therebelow, an aspect ratio of the second opening 70 is the same as that of the first opening 60 therebelow, and a length and a width of the second opening 70 increase in a proportion equal to the area of the second opening 70. In a case where the shape of the second opening 70 is diamond, as shown in FIG. 12B, the center of the second opening 70 and the center of the first opening 60 therebelow are at the same position, and a ratio between lengths of diagonals of the second opening 70 is the same as that of the first opening 60 therebelow, and the ratio of the second opening 70 increases in a proportion equal to the area of the second opening 70. In a case where the shape of the second opening 70 is circular, as shown in FIG. 12C, the center of the second opening 70 is at the same position as the center of the lower first opening 60, and a diameter of the second opening 70 increases in a proportion equal to the area thereof.

In some implementations, as shown in FIG. 11A, the minimum cross-sectional area S1 of the second opening and the minimum cross-sectional area S2 of the first opening corresponding to the second opening satisfy a relation of 1.08≤S2/S1≤1.22. Specifically, the minimum cross-sectional area S1 of the second opening and the minimum cross-sectional area S2 of the first opening corresponding to the second opening satisfy a relation of 1.1≤S2/S1≤1.2; in some implementations, the minimum cross-sectional area S1 of the second opening and the minimum cross-sectional area S2 of the first opening corresponding to the second opening satisfy a relation of 1.14≤S2/S1≤1.17; in some implementations, the minimum cross-sectional area S1 of the second opening and the minimum cross-sectional area S2 of the first opening corresponding to the second opening may satisfy a relation of S2/S1=1.1. In some implementations, the minimum cross-sectional area S1 of the second opening and the minimum cross-sectional area S2 of the first opening corresponding to the second opening may satisfy a relation of S2/S1=1.2. In a specific implementation, as shown in FIG. 11B, in a case where a ratio of the minimum cross-sectional area S1 (an area of QD) of the second opening to the minimum cross-sectional area S2 (an area of a backlight) of the first opening corresponding to the second opening is 1.1, 1.2, and 1.3, respectively, the brightness of the display panel is increased by 14%, 15%, and 15%, respectively. The increase of the area S1 of the second opening may result in a reduction of the resolution PPI of the display product, a increase of material used in the display product and thus a increase of the cost for manufacturing the display product, and in consideration of the above, the minimum cross-sectional area S1 of the second opening and the minimum cross-sectional area S2 of the first opening corresponding to the second opening are controlled to satisfy the relation of 1.08≤S2/S1≤1.22, so that the problem of serious attenuation in brightness and color cast at a large visual angle can be solved, and the resolution of the display product can be avoided to be reduced and other problems brought by reduced resolution can also be avoided.

As shown in FIG. 9B, R-QD sample-improvement 1 indicates a curve of an attenuation in brightness of an improved red pixel with viewing angles according to an embodiment of the present disclosure, where the refractive index n1 of the first film layer 4 is 1.8, the refractive index n2 of the matrix 301 is 1.65, and a ratio of the minimum cross-sectional area S1 of the second opening to the minimum cross-sectional area S2 of the first opening corresponding to the second opening is 1; R-QD sample is a curve of an attenuation in brightness of an unimproved red pixel with viewing angles, where the refractive index n1 of the first film layer 4 is 1.82, the refractive index n2 of the matrix 301 is 1.5, and the ratio of the minimum cross-sectional area S1 of the second opening to the minimum cross-sectional area S2 of the first opening corresponding to the second opening is 1; B indicates a curve of an attenuation in brightness of a blue OLED device (a light-emitting element) with viewing angles, and a ratio of the minimum cross-sectional area S1 of the second opening to the minimum cross-sectional area S2 of the first opening corresponding to the second opening is 1; as can be seen from the curve of the R-QD sample-improvement 1 and the curve of the R-QD sample, compared with the brightness of the unimproved red pixel, the brightness of the improved red pixel is higher at a large viewing angle, that is, the amount of light emitted from the red pixel at a large viewing angle can be increased by adjusting the refractive index n1 of the first film layer 4 and the refractive index n2 of the matrix 301.

As shown in FIG. 9C, R-QD sample-improvement 1 indicates a curve of an attenuation in color cast of an improved red pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; R-QD sample is a curve of an attenuation in color cast of an unimproved red pixel with viewing angles, where the refractive index n1 of the first film layer 4 is 1.82, the refractive index n2 of the matrix 301 is 1.5, and the ratio of the minimum cross-sectional area S1 of the second opening to the minimum cross-sectional area S2 of the first opening corresponding to the second opening is 1; B indicates a curve of an attenuation in color cast of a blue OLED device (a light-emitting element) with viewing angles, and the ratio of the minimum cross-sectional area S1 of the second opening to the minimum cross-sectional area S2 of the first opening corresponding to the second opening is 1; as can be seen from the curve of the R-QD sample-improvement 1 and the curve of the R-QD sample, at a large viewing angle, a value of the color cast of the improved red pixel in the present disclosure is reduced compared to a value of the color cast of the unimproved red pixel, that is, by adjusting the refractive index n1 of the first film layer 4 and the refractive index n2 of the matrix 301, the color cast of the red pixel at a large viewing angle can be reduced.

As shown in FIG. 9D, G-QD sample-improvement 1 indicates a curve of an attenuation in brightness of an improved green pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; G-QD sample is a curve of an attenuation in brightness of an unimproved green pixel with viewing angles, where the refractive index of the first film layer 4 is 1.82, the refractive index n2 of the matrix 301 is 1.5, and the ratio of the minimum cross-sectional area S1 of the second opening to the minimum cross-sectional area S2 of the first opening corresponding to the second opening is 1; B indicates a curve of an attenuation in brightness of a blue OLED device (a light-emitting element) with viewing angles, and a ratio of the minimum cross-sectional area S1 of the second opening to the minimum cross-sectional area S2 of the first opening corresponding to the second opening is 1; as can be seen from the curve of the G-QD sample-improvement 1 and the curve of the G-QD sample, the brightness of the improved green pixel in the present disclosure is higher than the brightness of the unimproved green pixel at a large viewing angle, that is, by adjusting the refractive index n1 of the first film layer 4 and the refractive index n2 of the matrix 301, the amount of light emitted from the green pixel at a large viewing angle can be increased.

As shown in FIG. 9E, G-QD sample-improvement 1 indicates a curve of an attenuation in color cast of an improved green pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; G-QD sample is a curve of an attenuation in color cast of an unimproved green pixel with viewing angles, where the refractive index of the first film layer 4 is 1.82, the refractive index n2 of the matrix 301 is 1.5, and the ratio of the minimum cross-sectional area S1 of the second opening to the minimum cross-sectional area S2 of the first opening corresponding to the second opening is 1; B indicates a curve of an attenuation in color cast of a blue OLED device (a light-emitting element) with viewing angles, and the ratio of the minimum cross-sectional area S1 of the second opening to the minimum cross-sectional area S2 of the first opening corresponding to the second opening is 1; as can be seen from the curve of the G-QD sample-improvement 1 and the curve of the G-QD sample, at a large viewing angle, a value of the color cast of the improved green pixel in the present disclosure is reduced compared to a value of the color cast of the unimproved green pixel, that is, by adjusting the refractive index n1 of the first film layer 4 and the refractive index n2 of the matrix 301, the color cast of the green pixel at a large viewing angle can be reduced.

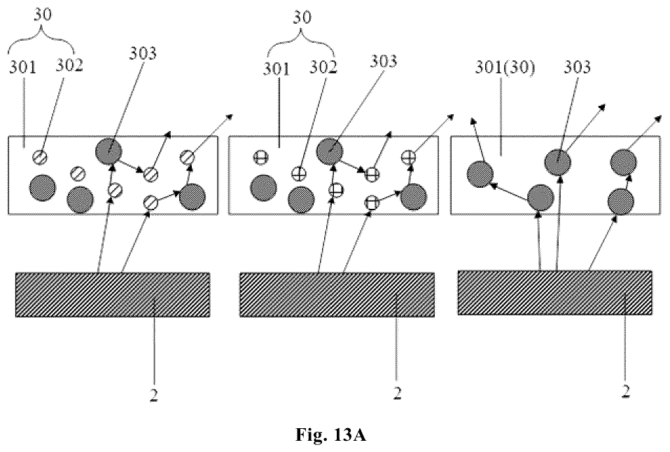

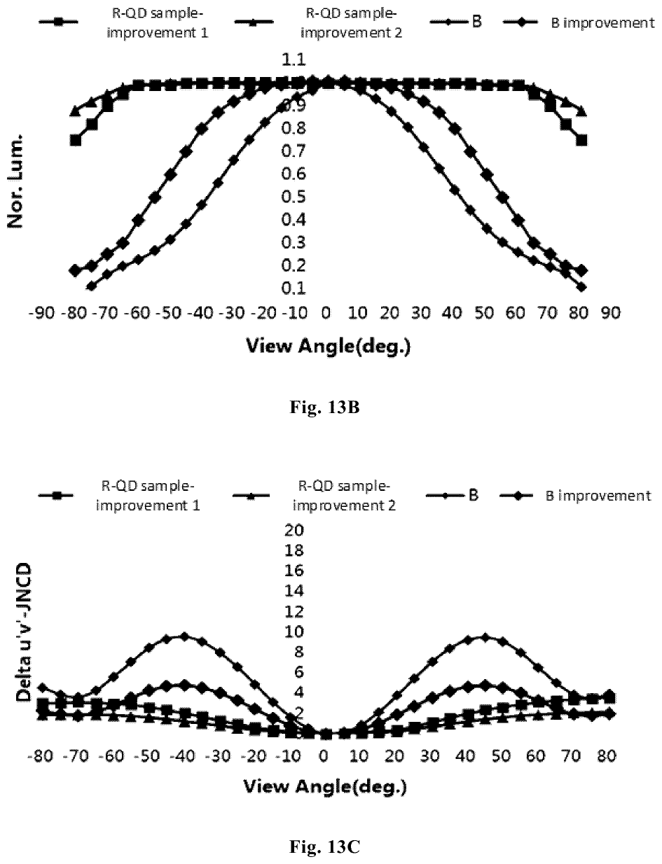

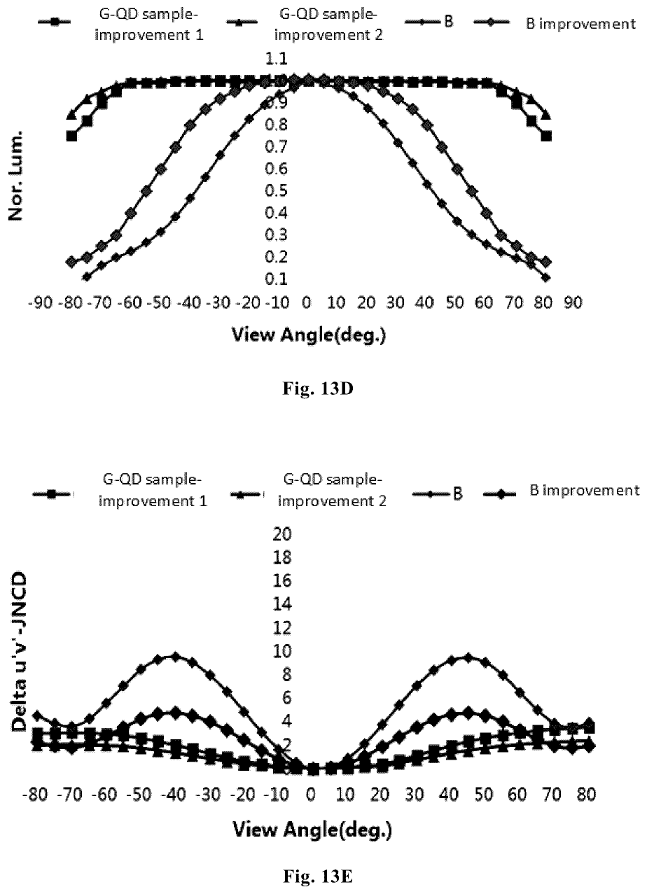

In some implementations, referring to FIG. 13A, the color conversion pattern 30 further includes scattering particles 303 distributed in the matrix 301, and at least 80% of the scattering particles 303 each have a particle size greater than 20 nm and less than 50 nm. In the embodiment of the present disclosure, the scattering particles 303 are added into the color conversion pattern 30, and the particle size of each scattering particle 303 is controlled, so that the uniformity of the light output at all angles of the color conversion pattern 30 is improved, and the problem of serious attenuation in brightness and color cast at a large viewing angle is further eliminated. Specifically, during forming the color conversion pattern 30, a mass percentage concentration of the scattering particles 303 is controlled, for example, the mass percentage concentration of the scattering particles 303 is controlled to be in a range from 5% to 10%, so that the uniformity of light output at all angles of the color conversion pattern 30 is improved, and the problem of serious attenuation in brightness and color cast at a large viewing angle is further eliminated.

As shown in FIG. 13B, R-QD sample-improvement 1 indicates a curve of an attenuation in brightness of an improved red pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; R-QD sample-improvement 2 is another curve of an attenuation in brightness of an improved red pixel with viewing angles, scattering particles 303 are added into the red pixel on the basis of the red pixel corresponding to the R-QD sample-improvement 1, and during forming the scattering particles 303 by printing, the mass percentage concentration of the scattering particles 303 in the printing ink is controlled to be 5%, and the thickness of the matrix 301 is controlled to be 10 μm; as can be seen from the curve of the R-QD sample-improvement 1 and the curve of the R-QD sample-improvement 2, compared with the brightness of the red pixel corresponding to the R-QD sample-improvement 1, the brightness of the red pixel, added with the scattering particles 303, corresponding to the R-QD sample-improvement 2 is higher at a large viewing angle, that is, by adding the scattering particles 303, the amount of light emitted from the red pixel at a large viewing angle can be increased; [symbol] B indicates a curve of an attenuation in brightness of an unimproved blue OLED device (a light-emitting element) with viewing angles; [symbol] B^{improvement} indicates a curve of an attenuation in brightness of an improved blue OLED device (a light-emitting element) with viewing angles, on the basis of the unimproved blue OLED device (a light-emitting element), scattering particles 303 are added into the improved blue OLED device, and during forming the scattering particles 303 by printing, the mass percentage concentration of the scattering particles 303 in the printing ink is controlled to be 5%, and the thickness of the matrix 301 is controlled to be 10 μm; as can be seen from the curve indicated by [symbol] B and the curve indicated by [symbol] B^{improvement}, at a large viewing angle, compared with the brightness of the blue pixel without the scattering particles added thereinto, the brightness of the blue pixel with the scattering particles 303 added thereinto is higher, that is, by adding the scattering particles 303, the amount of light emitted from the blue pixel at a large viewing angle can be increased, and a speed of the attenuation in brightness of the blue OLED device (the light-emitting element) added with the scattering particles 303 with viewing angles is obviously reduced.

As shown in FIG. 13C, R-QD sample-improvement 1 indicates a curve of an attenuation in color cast of an improved red pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; R-QD sample-improvement 2 is another curve of an attenuation in color cast of an improved red pixel with viewing angles, scattering particles 303 are added into the red pixel on the basis of the red pixel corresponding to the R-QD sample-improvement 1, and during forming the scattering particles 303 by printing, the mass percentage concentration of the scattering particles 303 in the printing ink is controlled to be 5%, and the thickness of the matrix 301 is controlled to be 10 μm; as can be seen from the curve of the R-QD sample-improvement 1 and the curve of the R-QD sample-improvement 2, at a large viewing angle, compared with a value of the color cast of the red pixel corresponding to the R-QD sample-improvement 1, a value of the color cast of the red pixel, added with the scattering particles 303, corresponding to the R-QD sample-improvement 2 is reduced, that is, by adding the scattering particles 303, the color cast of the red pixel at a large viewing angle can be reduced; [symbol] B indicates a curve of an attenuation in color cast of a blue OLED device (a light-emitting element) with viewing angles; [symbol] B^{improvement} indicates a curve of an attenuation in color cast of an improved blue OLED device (a light-emitting element) with viewing angles, on the basis of the unimproved blue OLED device (a light-emitting element), scattering particles 303 are added into the improved blue OLED device, and during forming the scattering particles 303 by printing, the mass percentage concentration of the scattering particles 303 in the printing ink is controlled to be 5%, and the thickness of the matrix 301 is controlled to be 10 μm; as can be seen from the curve indicated by [symbol] B and the curve indicated by [symbol] B^{improvement}, at a large viewing angle, compared with the value of the color cast of the blue pixel without the scattering particles added thereinto, the value of the color cast of the blue pixel with the scattering particles 303 added thereinto is reduced, that is, by adding the scattering particles 303, the color cast of the blue OLED device (the light-emitting element) at a large viewing angle can be reduced.

As shown in FIG. 13D, G-QD sample-improvement 1 indicates a curve of an attenuation in brightness of an improved green pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; G-QD sample-improvement 2 is another curve of an attenuation in brightness of an improved green pixel with viewing angles, scattering particles 303 are added into the green pixel on the basis of the green pixel corresponding to the G-QD sample-improvement 1, and during forming the scattering particles 303 by printing, the mass percentage concentration of the scattering particles 303 in the printing ink is controlled to be 5%, and the thickness of the matrix 301 is controlled to be 10 μm; as can be seen from the curve of the G-QD sample-improvement 1 and the curve of the G-QD sample-improvement 2, at a large viewing angle, compared with the brightness of the green pixel corresponding to the G-QD sample-improvement 1, the brightness of the green pixel, added with the scattering particles 303, corresponding to the G-QD sample-improvement 2 is higher, that is, by adding the scattering particles 303, the amount of light emitted from the green pixel at a large viewing angle can be increased; [symbol] B indicates a curve of an attenuation in brightness of an unimproved blue light-emitting device (a light-emitting element) with viewing angles; [symbol] B^{improvement} indicates a curve of an attenuation in brightness of an improved blue OLED device (a light-emitting element) with viewing angles, on the basis of the unimproved blue OLED device (a light-emitting element), scattering particles 303 are added into the improved blue OLED device, and during forming the scattering particles 303 by printing, the mass percentage concentration of the scattering particles 303 in the printing ink is controlled to be 5%, and the thickness of the matrix 301 is controlled to be 10 μm; as can be seen from the curve indicated by [symbol] B and the curve indicated by [symbol] B^{improvement}, at a large viewing angle, compared with the brightness of the blue pixel without the scattering particles added thereinto, the brightness of the blue pixel with the scattering particles 303 added thereinto is higher, that is, by adding the scattering particles 303, the amount of light emitted from the blue pixel at a large viewing angle can be increased, and a speed of the attenuation in brightness of the blue OLED device (the light-emitting element) added with the scattering particles 303 with viewing angles is obviously reduced.

As shown in FIG. 13E, G-QD sample-improvement 1 indicates a curve of an attenuation in color cast of an improved green pixel with viewing angles according to an embodiment of the present disclosure, where the refractive index n1 of the first film layer 4 is 1.8, the refractive index n2 of the matrix 301 is 1.65, and the ratio of the minimum cross-sectional area S1 of the second opening to the minimum cross-sectional area S2 of the first opening corresponding to the second opening is 1; G-QD sample-improvement 2 is another curve of an attenuation in color cast of an improved green pixel with viewing angles, scattering particles 303 are added into the green pixel on the basis of the green pixel corresponding to the G-QD sample-improvement 1, and during forming the scattering particles 303 by printing, the mass percentage concentration of the scattering particles 303 in the printing ink is controlled to be 5%, and the thickness of the matrix 301 is controlled to be 10 μm; as can be seen from the curve of the G-QD sample-improvement 1 and the curve of the G-QD sample-improvement 2, at a large viewing angle, compared with a value of the color cast of the green pixel corresponding to the G-QD sample-improvement 1, a value of the color cast of the green pixel, added with the scattering particles 303, corresponding to the G-QD sample-improvement 2 is reduced, that is, by adding the scattering particles 303, the color cast of the green pixel at a large viewing angle can be reduced; [symbol] B indicates a curve of an attenuation in color cast of an unimproved blue OLED device (a light-emitting element) with viewing angles; [symbol] B^{improvement} indicates a curve of an attenuation in color cast of an improved blue OLED device (a light-emitting element) with viewing angles, on the basis of the unimproved blue OLED device (a light-emitting element), scattering particles 303 are added into the improved blue OLED device, and during forming the scattering particles 303 by printing, the mass percentage concentration of the scattering particles 303 in the printing ink is controlled to be 5%, and the thickness of the matrix 301 is controlled to be 10 μm; as can be seen from the curve indicated by [symbol] B and the curve indicated by [symbol] ^{improvement}, at a large viewing angle, compared with the value of the color cast of the blue pixel without the scattering particles added thereinto, the value of the color cast of the blue pixel with the scattering particles 303 added thereinto is reduced, that is, by adding the scattering particles 303, the color cast of the blue OLED device (the light-emitting element) at a large viewing angle can be reduced.

In some implementations, referring to FIG. 14, the display panel further includes a low refractive index layer 54 located on a side of the color conversion film layer 3 away from the first film layer 4, the low refractive index layer 54 has a refractive index greater than 1.3 and less than 1.4 and is configured to reflect light emitted from the light-emitting element 2 and transmitting through the color conversion film layer 3 back to the color conversion film layer 3. Specifically, the low refractive index layer 54 may be divided into a matrix layer and an additive layer, the matrix layer being made of epoxy resin, and the additive layer being made of SiOx; a thickness of the low refractive index layer 54 may be set to be in a range from 30 μm to 50 μm, the low refractive index layer 54 plays a main role of allowing a part of blue light transmitting through the color conversion film layer 3 to enter the color conversion film layer 3 again through total reflection, and excite corresponding photons to improve the conversion rate of the color conversion pattern 30.

In some implementations, as shown in FIG. 14, the display panel further includes a black matrix 8 on a side of the low refractive index layer 54 away from the color conversion film layer 3, and a plurality of color filters 9; the black matrix 8 has a plurality of third openings 80, and the color filters 9 are respectively located in the third openings 80 to further improve the color gamut of the product. The color filters 9 specifically includes a red filter 91, a green filter 92 and a blue filter 93; the red block 91 corresponds to the red conversion pattern 31, and only transmits red light and absorb light in any other wavelength band which is not completely converted into red light; the green color filter 92 corresponds to the green conversion pattern 32, and only transmits the green light and absorb light in any other wavelength band which is not completely converted into the green light; the blue color filter 93 corresponds to the blue conversion pattern 33, and only transmits the blue light and absorb light in any other wavelength band which is not completely converted into the blue light.

In some implementations, as shown in FIG. 14, the display panel further includes a planarization layer 56 located between the black matrix 8 and the low refractive index layer 54 for planarization, thereby facilitating the subsequent formation of the black matrix 8 and the color filters 9.

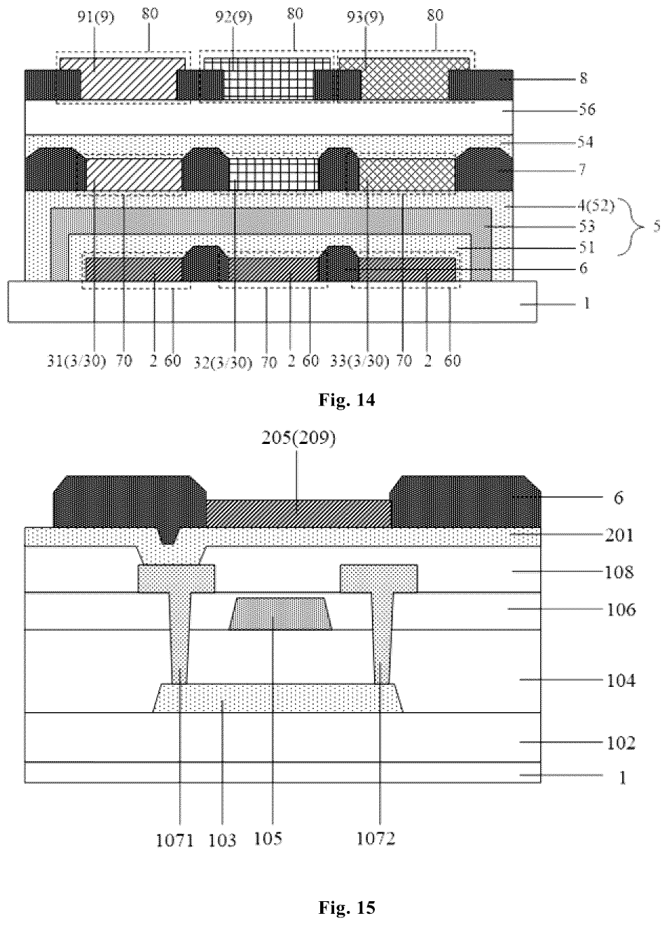

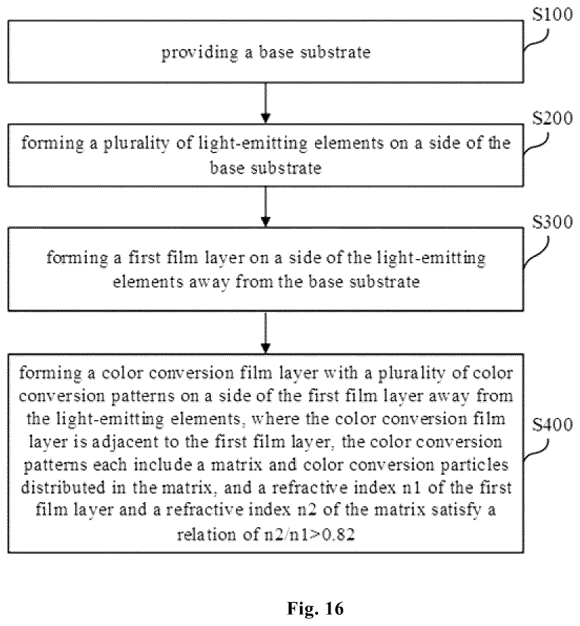

In a specific implementation, the display panel may include a pixel circuit located between the base substrate 1 and the light-emitting element 2 to drive the light-emitting element 2 to emit light, and the pixel circuit may specifically include a thin film transistor and a capacitor. Specifically, as shown in FIG. 15, the thin film transistor may include a buffer layer 102 (a material of which may specifically be SiOx and/or SiNx), an active layer 103 (a material of which may specifically be p-Si formed by performing a laser annealing process on a-Si), a gate insulating layer 104 (a material of which may specifically be SiOx and/or SiNx), a gate 105 (a material of which may specifically be Mo or Cu), an interlayer dielectric layer 106 (a material of which may specifically be SiOx and/or SiNx), a source and drain layer (which may include a source electrode 1071 and a drain electrode 1072), and a planarization layer 108 (a material of which may specifically be polyimide), which are sequentially located on a side of the base substrate 1. A material of the anode (the first anode 201 or the second anode 212) may be ITO/Ag/ITO. A material of the first pixel defining layer 6 may be polyimide. A material of the base substrate 1 may be polyimide.

An embodiment of the disclosure further provides a display apparatus, which includes the display panel provided by the embodiments of the present disclosure.

Referring to FIG. 16, an embodiment of the present disclosure further provides a method for manufacturing a display panel, where the method includes:

Step S100, providing a base substrate;

Step S200, forming a plurality of light-emitting elements on a side of the base substrate;

Step S300, forming a first film layer on a side of the light-emitting elements away from the base substrate;

Step S400, forming a color conversion film layer with a plurality of color conversion patterns on a side of the first film layer away from the light-emitting elements, where the color conversion film layer is adjacent to the first film layer, the color conversion patterns each include a matrix and color conversion particles distributed in the matrix, and a refractive index n1 of the first film layer and a refractive index n2 of the matrix satisfy a relation of n2/n1>0.82.

In the embodiment of the present disclosure, the first film layer 4 adjacent to the color conversion film layer 3 is disposed between the light-emitting elements 2 and the color conversion film layer 3, and the refractive index n1 of the first film layer 4 and the refractive index n2 of the matrix 301 satisfy a relation of n2/n1>0.821, which can increase the critical angle of total reflection at the interface between the first film layer 4 and the color conversion film layer 3, increase the amount of light emitted at a large viewing angle, and further eliminate the problem of serious attenuation in brightness and color cast of the display device including QD and OLED in the related art at a large viewing angle.

It should be noted that, in the embodiment of the present disclosure, the expressions of in a range from A to B or ranging from A to B all include A and B endpoints. For example, the mass percent concentration being in a range from 5% to 10% including the endpoint value of 5% and the endpoint value of 10%.

While preferred embodiments of the present invention have been described, additional variations and modifications in those embodiments may be made by a person skilled in the art once he or she learns of the basic creative concepts. Therefore, it is intended that the appended claims be interpreted as including the preferred embodiment and all changes and modifications that fall within the scope of the invention.

It will be apparent to a person skilled in the art that various modifications and variations can be made from the embodiments of the present disclosure without departing from the spirit or scope of the embodiments of the present disclosure. Thus, if such modifications and variations of the embodiments of the present disclosure fall within the scope of the claims of the present disclosure and their equivalents, the present disclosure is also intended to encompass these modifications and variations.

1. A display panel, comprising:
a base substrate;
light-emitting elements located on a side of the base substrate;
a color conversion film layer located on a side, away from the base substrate, of the light-emitting elements and comprising a plurality of color conversion patterns in one-to-one correspondence with the light-emitting elements, wherein each color conversion pattern comprises a matrix and color conversion particles distributed in the matrix, and the color conversion particles are configured to convert light emitted by a corresponding light-emitting element; and
a first film layer located between the light-emitting elements and the color conversion film layer and adjacent to the color conversion film layer, a refractive index n1 of the first film layer and a refractive index n2 of the matrix satisfying:
n2/n1>0.82.

2. The display panel of claim 1, wherein a critical angle of total reflection at an interface between the first film layer and the matrix is greater than 55°.

3. The display panel of claim 1, wherein the refractive index n1 of the first film layer and the refractive index n2 of the matrix satisfy: n2/n1≥0.91.

4. The display panel of claim 2, wherein the refractive index n1 of the first film layer satisfies: 1.76≤n1≤1.80.

5. The display panel according to claim 2, wherein the refractive index n2 of the matrix satisfies: 1.58≤n2≤1.65.

6. The display panel of claim 1, wherein a material of the first film layer comprises silicon nitride and silicon oxynitride, wherein a mass of silicon nitride is m1 and a sum of masses of silicon nitride and silicon oxynitride is m2, and m1 and m2 satisfy: 40%≤m1/m2≤45%.

7. The display panel of claim 1, further comprising an encapsulation layer for light-emitting element between the light-emitting elements and the color conversion film layer, the encapsulation layer for light-emitting element comprising a first inorganic encapsulation layer, an organic encapsulation layer located on a side of the first inorganic encapsulation layer away from the light-emitting elements, and a second inorganic encapsulation layer located on a side of the organic encapsulation layer away from the first inorganic encapsulation layer:
wherein the first film layer is the second inorganic encapsulation layer.

8. The display panel of claim 1, further comprising a filling layer between the light-emitting elements and the color conversion film layer, the first film layer being the filling layer.

9. The display panel of claim 8, further comprising an encapsulation layer for quantum dot located between the filling layer and the color conversion film layer, the first film layer being the encapsulation layer for quantum dot.

10. The display panel of claim 1, wherein a material of the matrix comprises at least one of a phenolic resin, a polyamide resin, a polyimide, a polyester resin, a polyphenylene resin.

11. The display panel of claim 1, further comprising:
a first pixel defining layer located between the base substrate and the first film layer, the first pixel defining layer having a plurality of first openings; and
a second pixel defining layer located on a side of the first film layer away from the first pixel defining layer, the second pixel defining layer having a plurality of second openings, the color conversion patterns being located in the second openings, and at least part of the second openings being in one-to-one correspondence with the first openings,
wherein an orthographic projection of each of the at least part of the second openings on the base substrate covers an orthographic projection of the first opening corresponding to the second opening on the base substrate, and a minimum cross-sectional area of each of the at least part of the second openings is larger than a minimum cross-sectional area of the first opening corresponding thereto.

12. The display panel of claim 11, wherein the minimum cross-sectional area S1 of each of the at least part of the second openings and the minimum cross-sectional area S2 of the first opening corresponding thereto satisfy: 1.08≤S1/S2≤1.22.

13. The display panel of claim 1, wherein each color conversion pattern further comprises scattering particles distributed in the matrix, at least 80% of the scattering particles having a particle size larger than or equal to 20 nm and less than or equal to 50 nm.

14. The display panel of claim 1, further comprising a low refractive index layer located on a side of the color conversion film layer away from the first film layer, the low refractive index layer having a refractive index larger than or equal to 1.3 and less than or equal to 1.4.

15. The display panel according to claim 14, wherein the light-emitting elements emit blue light:
the plurality of color conversion patterns comprise a red conversion pattern, a green conversion pattern, and a blue conversion pattern, the red conversion pattern comprising red conversion particles, the green conversion pattern comprising green conversion particles, and the blue conversion pattern comprising blue conversion particles or a transparent color filter;
the display panel further comprises a black matrix and a plurality of color filters located on a side, away from the color conversion film layer, of the low refractive index layer: the black matrix being provided with a plurality of third openings, and the color filters being located in the third openings, respectively: the plurality of color filters comprising a red color filter corresponding to the red conversion pattern, a green color filter corresponding to the green conversion pattern, and a blue color filter corresponding to the blue conversion pattern.

16. The display panel of claim 1, wherein the color convertion particles comprise quantum dots.

17. The display panel according to claim 1, wherein the light-emitting elements are OLED light-emitting elements.

18. A display apparatus, comprising the display panel of claim 1.

19. A method for manufacturing a display panel, comprising:
providing a base substrate;
forming a plurality of light-emitting elements on a side of the base substrate;
forming a first film layer on a side of the light-emitting elements away from the base substrate;
forming a color conversion film layer having a plurality of color conversion patterns on a side of the first film layer away from the light-emitting elements, wherein the color conversion film layer is adjacent to the first film layer, the color conversion patterns each comprise a matrix and color conversion particles distributed in the matrix, and a refractive index n1 of the first film layer and a refractive index n2 of the matrix satisfy: n2/n1>0.82.

20. The display panel of claim 2, further comprising an encapsulation layer for light-emitting element between the light-emitting elements and the color conversion film layer, the encapsulation layer for light-emitting element comprising a first inorganic encapsulation layer, an organic encapsulation layer located on a side of the first inorganic encapsulation layer away from the light-emitting elements, and a second inorganic encapsulation layer located on a side of the organic encapsulation layer away from the first inorganic encapsulation layer:
wherein the first film layer is the second inorganic encapsulation layer.
